(19) United States
(12) Patent Application Publication
(10) Pub. No.: US 2025/0060684 A1
(43) Pub. Date: Feb. 20, 2025

(54) AN OPTICAL SYSTEM IMPLEMENTED IN A SYSTEM FOR FAST OPTICAL INSPECTION OF TARGETS

(71) Applicant: ASML Netherlands B.V., Veldhoven (NL)

(72) Inventors: Simon Reinald HUISMAN, Eindhoven (NL); Sebastianus Adrianus GOORDEN, Eindhoven (NL); Stephen ROUX, New Fairfield, CT (US)

(73) Assignee: ASML Netherlands B.V., Veldhoven (NL)

(21) Appl. No.: 18/724,286

(22) PCT Filed: Dec. 14, 2022
(86) PCT No.: PCT/EP2022/085775

§ 371 Date: Jun. 26, 2024

Related U.S. Application Data
(60) Provisional application No. 63/294,262, filed on Dec. 28, 2021.

(51) Int. Cl. G03F 9/00

(52) U.S. Cl. CPC G03F 9/7069; G03F 9/7088; G03F 9/7092

(57) ABSTRACT

A system includes optical devices, reflective devices, a movable reflective device, and a detector. The optical devices are disposed at a first plane and around a axis of the system and receive scattered radiation from targets. The reflective devices are disposed at at least a second plane and around the axis. Each of the reflective devices receives the scattered radiation from a corresponding one of the optical devices. The movable reflective device is disposed along the axis and receives the scattered radiation from each of the reflective devices. The detector receives the scattered radiation from the movable reflective device.

### CROSS-REFERENCE TO RELATED APPLICATIONS

This application claims priority of U.S. Provisional Patent Application No. 63/294,262, which was filed on Dec. 28, 2021, and which is incorporated herein in its entirety by reference.

### FIELD

The present disclosure relates to inspection devices and methods, for example, a scatterometer used for metrology in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

A lithographic system can output only a finite number of fabricated devices in a given time frame.

### SUMMARY

Accordingly, it is desirable to improve routines and processes used in lithographic systems to increase fabrication speed and throughput. For example, optical inspection processes may be performed faster based on embodiments described herein.

In some embodiments, a system comprises optical devices, reflective devices, a movable reflective device, and a detector. The optical devices are disposed at a first plane and around a axis of the system and are configured to receive scattered radiation from targets. The reflective devices are disposed at at least a second plane and around the axis. Each of the reflective devices is configured to receive the scattered radiation from a corresponding one of the optical devices. The movable reflective device is disposed along the axis and is configured to receive the scattered radiation from each of the reflective devices. The detector is configured to receive the scattered radiation from the movable reflective device.

In some embodiments, an optical system comprises optical devices, reflective devices, and a movable reflective device. The optical devices are disposed at a first plane and around a axis of the system and are configured to receive scattered radiation from targets. The reflective devices are disposed at at least a second plane and around the axis. Each of the reflective devices is configured to receive the scattered radiation from a corresponding one of the optical devices. The movable reflective device is disposed along the axis and is configured to receive the scattered radiation from each of the reflective devices.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of inspection apparatuses, according to some embodiments.

FIG. 5A shows an optical system, according to some embodiments.

FIGS. 5B and 5C show optical arrangements using elements of FIG. 5A, according to some embodiments.

FIG. 6A shows an optical system, according to some embodiments.

FIG. 6B shows an optical arrangement using elements of FIG. 6A, according to some embodiments.

FIG. 7A shows an optical system, according to some embodiments.

FIG. 7B shows an optical arrangement using elements of FIG. 7A, according to some embodiments.

FIG. 8 shows an optical system, according to some embodiments.

FIG. 9 shows a movable reflective device, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., +10%, +20%, or +30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

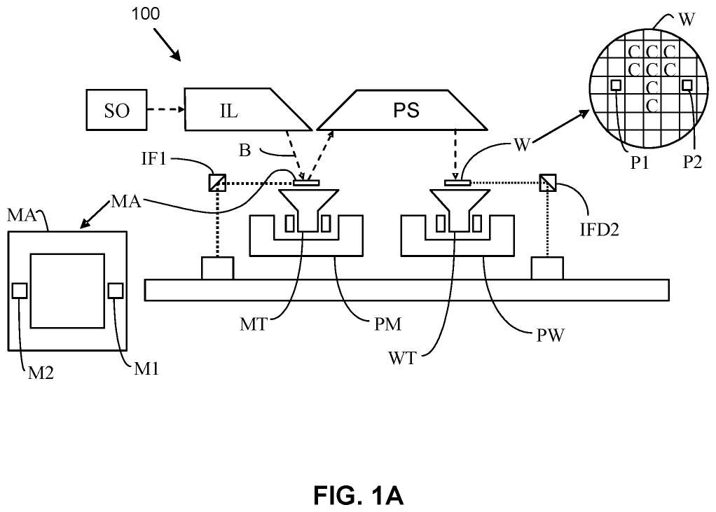

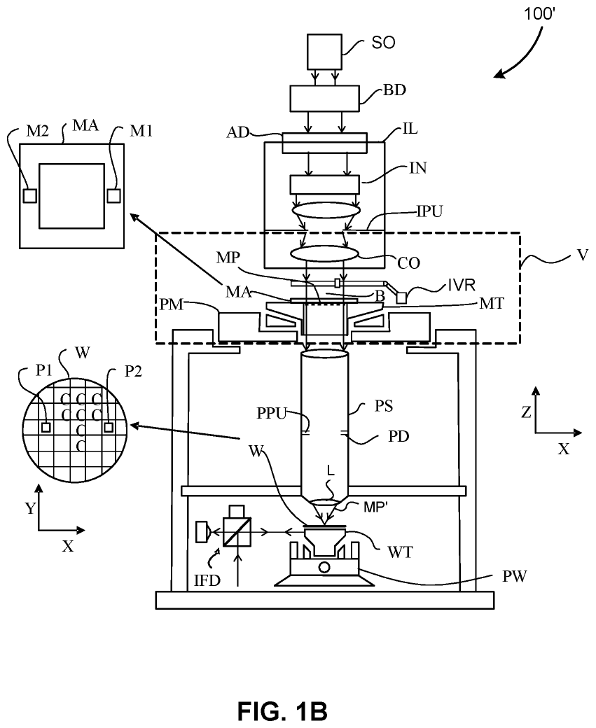

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The terms “inspection apparatus.” “metrology system,” or the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

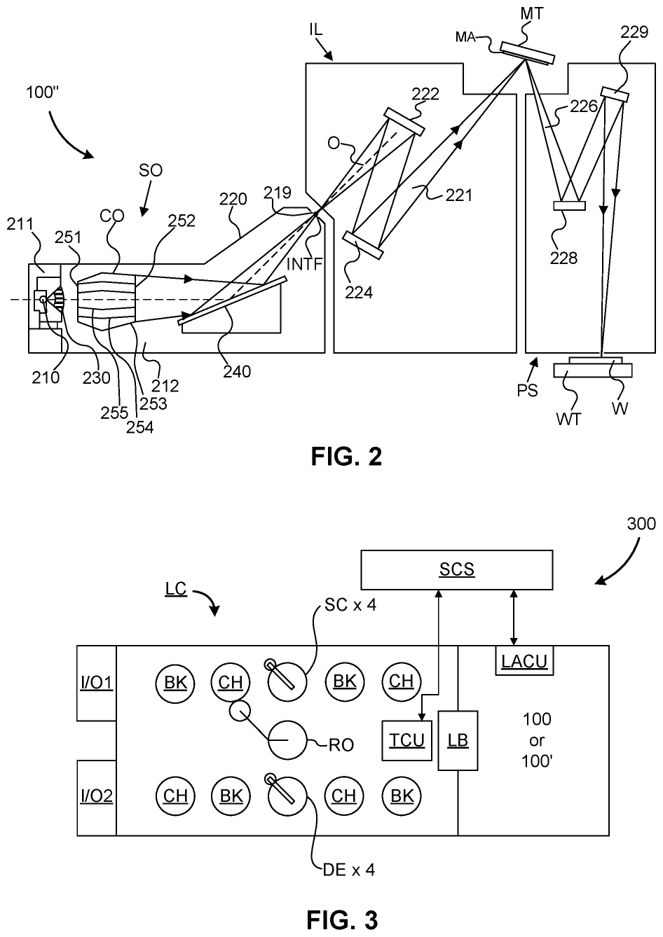

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li. Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Exemplary Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement may be performed using the techniques described in U.S. Publication No. 2009/195768 A (Bijnen et al.), however. The full contents of both of these disclosures are incorporated herein by reference.

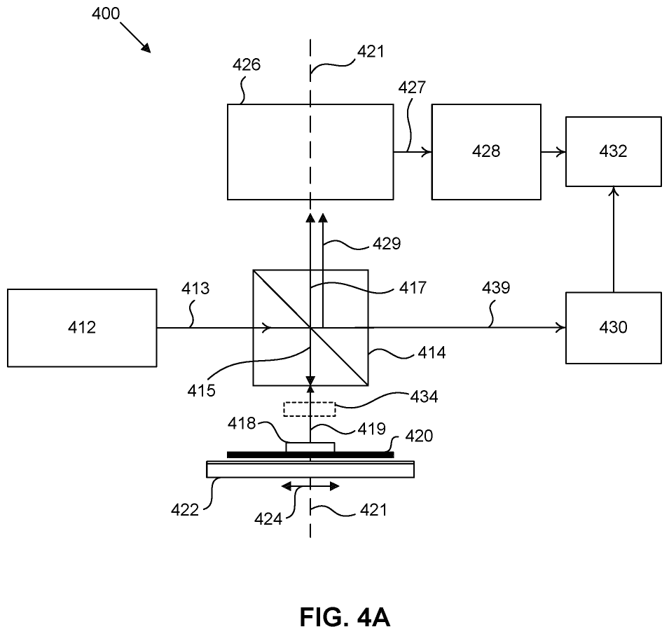

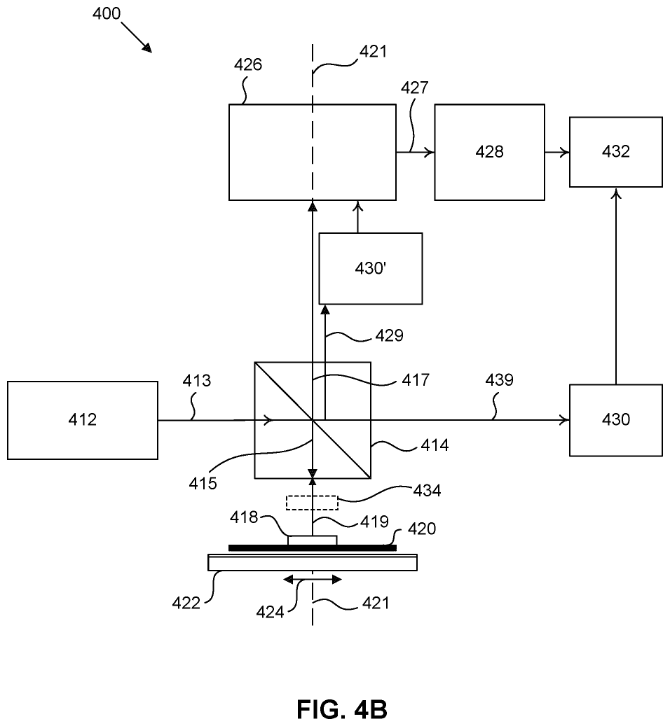

FIG. 4A shows a schematic of a cross-sectional view of an inspection apparatus

400 that may be implemented as a part of lithographic apparatus 100 or 100′, according to some embodiments. In some embodiments, inspection apparatus 400 may be configured to align a substrate (e.g., substrate W) with respect to a patterning device (e.g., patterning device MA). Inspection apparatus 400 may be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

In some embodiments, inspection apparatus 400 may include an illumination system 412, a beam splitter 414, an interferometer 426, a detector 428, a beam analyzer 430, and an overlay calculation processor 432. Illumination system 412 may be configured to provide an electromagnetic narrow band radiation beam 413 having one or more passbands. In an example, the one or more passbands may be within a spectrum of wavelengths between about 500 nm to about 900 nm. In another example, the one or more passbands may be discrete narrow passbands within a spectrum of wavelengths between about 500 nm to about 900 nm. Illumination system 412 may be further configured to provide one or more passbands having substantially constant center wavelength (CWL) values over a long period of time (e.g., over a lifetime of illumination system 412). Such configuration of illumination system 412 may help to prevent the shift of the actual CWL values from the desired CWL values, as discussed above, in current alignment systems. And, as a result, the use of constant CWL values may improve long-term stability and accuracy of alignment systems (e.g., inspection apparatus 400) compared to the current alignment apparatuses.

In some embodiments, beam splitter 414 may be configured to receive radiation beam 413 and split radiation beam 413 into at least two radiation sub-beams. For example, radiation beam 413 may be split into radiation sub-beams 415 and 417, as shown in FIG. 4A. Beam splitter 414 may be further configured to direct radiation sub-beam 415 onto a substrate 420 placed on a stage 422. In one example, the stage 422 is movable along direction 424. Radiation sub-beam 415 may be configured to illuminate an alignment mark or a target 418 located on substrate 420. Alignment mark or target 418 may be coated with a radiation sensitive film. In some embodiments, alignment mark or target 418 may have one hundred and eighty degrees (i.e., 180°) symmetry. That is, when alignment mark or target 418 is rotated 180° about an axis of symmetry perpendicular to a plane of alignment mark or target 418, rotated alignment mark or target 418 may be substantially identical to an unrotated alignment mark or target 418. The target 418 on substrate 420 may be (a) a resist layer grating comprising bars that are formed of solid resist lines, or (b) a product layer grating, or (c) a composite grating stack in an overlay target structure comprising a resist grating overlaid or interleaved on a product layer grating. The bars may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In some embodiments, beam splitter 414 may be further configured to receive diffraction radiation beam 419 and split diffraction radiation beam 419 into at least two radiation sub-beams, according to an embodiment. Diffraction radiation beam 419 may be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements may be used to obtain the similar result of illuminating alignment mark or target 418 on substrate 420 and detecting an image of alignment mark or target 418.

As illustrated in FIG. 4A, interferometer 426 may be configured to receive radiation sub-beam 417 and diffracted radiation sub-beam 429 through beam splitter 414. In an example embodiment, diffracted radiation sub-beam 429 may be at least a portion of radiation sub-beam 415 that may be reflected from alignment mark or target 418. In an example of this embodiment, interferometer 426 comprises any appropriate set of optical-elements, for example, a combination of prisms that may be configured to form two images of alignment mark or target 418 based on the received diffracted radiation sub-beam 429. It should be appreciated that a good quality image need not be formed, but that the features of alignment mark 418 should be resolved. Interferometer 426 may be further configured to rotate one of the two images with respect to the other of the two images 180° and recombine the rotated and unrotated images interferometrically.

In some embodiments, detector 428 may be configured to receive the recombined image via interferometer signal 427 and detect interference as a result of the recombined image when alignment axis 421 of inspection apparatus 400 passes through a center of symmetry (not shown) of alignment mark or target 418. Such interference may be due to alignment mark or target 418 being 180° symmetrical, and the recombined image interfering constructively or destructively, according to an example embodiment. Based on the detected interference, detector 428 may be further configured to determine a position of the center of symmetry of alignment mark or target 418 and consequently, detect a position of substrate 420. According to an example, alignment axis 421 may be aligned with an optical beam perpendicular to substrate 420 and passing through a center of image rotation interferometer 426. Detector 428 may be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data may, for example, be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 may be configured to receive and determine an optical state of diffracted radiation sub-beam 439. The optical state may be a measure of beam wavelength, polarization, or beam profile. Beam analyzer 430 may be further configured to determine a position of stage 422 and correlate the position of stage 422 with the position of the center of symmetry of alignment mark or target 418. As such, the position of alignment mark or target 418 and, consequently, the position of substrate 420 may be accurately known with reference to stage 422. Alternatively, beam analyzer 430 may be configured to determine a position of inspection apparatus 400 or any other reference element such that the center of symmetry of alignment mark or target 418 may be known with reference to inspection apparatus 400 or any other reference element. Beam analyzer 430 may be a point or an imaging polarimeter with some form of wavelength-band selectivity. In some embodiments, beam analyzer 430 may be directly integrated into inspection apparatus 400, or connected via fiber optics of several types: polarization preserving single mode, multimode, or imaging, according to other embodiments.

In some embodiments, beam analyzer 430 may be further configured to determine the overlay data between two patterns on substrate 420. One of these patterns may be a reference pattern on a reference layer. The other pattern may be an exposed pattern on an exposed layer. The reference layer may be an etched layer already present on substrate 420. The reference layer may be generated by a reference pattern exposed on the substrate by lithographic apparatus 100 and/or 100′. The exposed layer may be a resist layer exposed adjacent to the reference layer. The exposed layer may be generated by an exposure pattern exposed on substrate 420 by lithographic apparatus 100 or 100′. The exposed pattern on substrate 420 may correspond to a movement of substrate 420 by stage 422. In some embodiments, the measured overlay data may also indicate an offset between the reference pattern and the exposure pattern. The measured overlay data may be used as calibration data to calibrate the exposure pattern exposed by lithographic apparatus 100 or 100′, such that after the calibration, the offset between the exposed layer and the reference layer may be minimized.

In some embodiments, beam analyzer 430 may be further configured to determine a model of the product stack profile of substrate 420, and may be configured to measure overlay, critical dimension, and focus of target 418 in a single measurement. The product stack profile contains information on the stacked product such as alignment mark, target 418, or substrate 420, and may include mark process variation-induced optical signature metrology that is a function of illumination variation. The product stack profile may also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 may be further configured to process information related to a particular property of an exposed pattern in that layer. For example, beam analyzer 430 may process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) may be connected to beam analyzer 430, and allows the possibility of accurate stack profile detection as discussed below. For example, detector 428 may be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that may be read-out at high speed and are especially of interest if phase-stepping detection is used.

In some embodiments, a second beam analyzer 430′ may be configured to receive and determine an optical state of diffracted radiation sub-beam 429, as shown in FIG. 4B. The optical state may be a measure of beam wavelength, polarization, or beam profile. Second beam analyzer 430′ may be identical to beam analyzer 430. Alternatively, second beam analyzer 430′ may be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, may be accurately known with reference to stage 422. Second beam analyzer 430′ may also be configured to determine a position of inspection apparatus 400, or any other reference element, such that the center of symmetry of alignment mark or target 418 may be known with reference to inspection apparatus 400, or any other reference element. Second beam analyzer 430′ may be further configured to determine the overlay data between two patterns and a model of the product stack profile of substrate 420. Second beam analyzer 430′ may also be configured to measure overlay, critical dimension, and focus of target 418 in a single measurement.

In some embodiments, second beam analyzer 430′ may be directly integrated into inspection apparatus 400, or it may be connected via fiber optics of several types: polarization preserving single mode, multimode, or imaging, according to other embodiments. Alternatively, second beam analyzer 430′ and beam analyzer 430 may be combined to form a single analyzer (not shown) configured to receive and determine the optical states of both diffracted radiation sub-beams 429 and 439.

In some embodiments, processor 432 receives information from detector 428 and beam analyzer 430. For example, processor 432 may be an overlay calculation processor. The information may comprise a model of the product stack profile constructed by beam analyzer 430. Alternatively, processor 432 may construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 may create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 may utilize the basic correction algorithm to characterize the inspection apparatus 400 with reference to wafer marks and/or alignment marks 418.

In some embodiments, processor 432 may be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 may utilize a clustering algorithm to group the marks into sets of similar constant offset error, and create an alignment error offset correction table based on the information. The clustering algorithm may be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error may be deduced. Table 1 illustrates how this may be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value may be taken to be the reference point and, relative to this, the offset may be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 may also be obtained from marks and target 418 under different illumination settings, the illumination setting, which results in the smallest overlay error, and its corresponding calibration factor, may be determined and selected. Following this, processor 432 may group marks into sets of similar overlay error. The criteria for grouping marks may be adjusted based on different process controls, for example, different error tolerances for different processes.

In some embodiments, processor 432 may confirm that all or most members of the group have similar offset errors, and apply an individual offset correction from the clustering algorithm to each mark, based on its additional optical stack metrology. Processor 432 may determine corrections for each mark and feed the corrections back to lithographic apparatus 100 or 100′ for correcting errors in the overlay, for example, by feeding corrections into the inspection apparatus 400.

### Exemplary Optical Systems

In some embodiments, the term “throughput” may be used to describe the rate at which a wafer clears a particular fabrication step and moves to the next step. Throughput may be a performance marker of marketability of a lithographic system. It is desirable for lithographic systems to output as many products as possible in as little time as possible. Lithographic fabrication may comprise several complex processes. Each process encompasses choices in technology that balance desired qualities (e.g., sub-nanometer accuracy, high yield) and drawbacks (e.g., slower fabrication, cost). Such processes may involve inspection of printed marks on a substrate. An inspection apparatus may be used in connection with a lithographic process, for example, to ascertain a conformity of a printed pattern on a substrate or to align a substrate in order to properly receive a new pattern. It should be appreciated that an inspection process may greatly enhance mass production using lithographic processes. It should also be appreciated that the inspection process may have an associated time cost, thereby reducing throughput.

Some embodiments herein include devices and functions to enhance speeds of inspection processes.

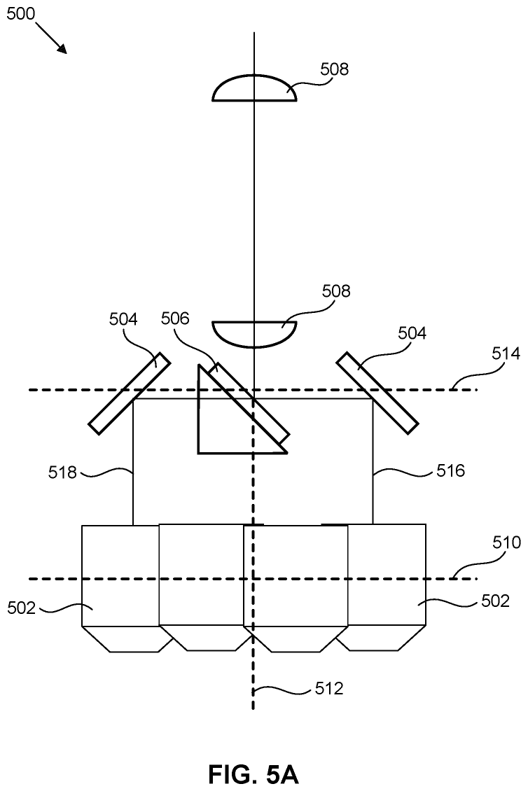

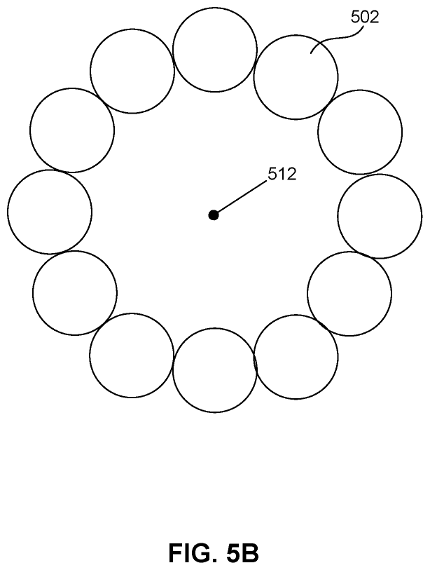

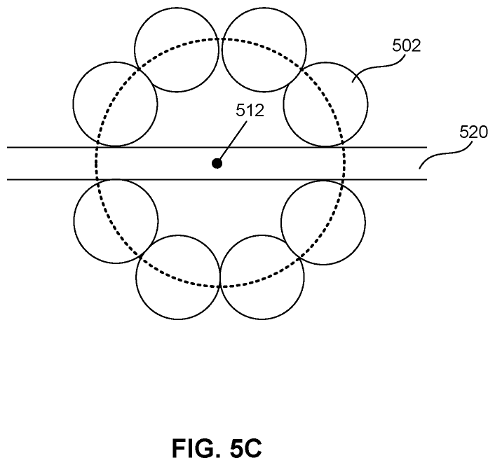

FIG. 5A shows an optical system 500, according to some embodiments. In some embodiments, optical system 500 may comprise optical devices 502, reflective devices 504, and a movable reflective device 506. Optical system 500 may also comprise a lens system 508 (e.g., one or more lenses, 4f lens system, or the like).

In some embodiments, optical devices 502 may comprise objectives. An objective is an optical device that collects radiation scattered from a target and/or focuses the radiation to produce an image of the target. Objectives may comprise, for example, one or more lenses, one or more mirrors, or combinations of several optical elements. Optical devices 502 may be disposed at a plane 510 (e.g., a first plane). Optical devices 502 may be arranged around an axis 512 of optical system 500. Axis 512 may be a central axis of optical system 500. Reflective devices 504 may be disposed at a plane 514 (e.g., a second plane). Reflective devices may be arranged around axis 512. Reflective devices 504 may have a one-to-one correspondence with optical devices 502. Movable reflective device 506 may be disposed along axis 512. Lens system 508 may be disposed along axis 512.

It should be appreciated that, in some embodiments, enumerative adjectives (e.g., “first.” “second.” “third,” or the like) may be used as entity identifiers, as opposed to an order of introduction (unless otherwise noted). For example, the terms “a first plane” and “a second plane” may distinguish two planes, but need not specify which plane comes before the other. Furthermore, an object in a drawing need not be limited to the enumerative adjective used in this Detailed Description (e.g., plane 510 may be referred to as a second plane if other plane(s) use distinguishing enumerative adjective(s)).

In some embodiments, optical devices 502 may receive scattered radiation from a plurality of targets 418 (FIG. 4). Though FIG. 4 illustrates only one target (for clarity reasons), it should be appreciated that substrate undergoing a lithographic process may receive a pattern that comprises a plurality of targets (e.g., several tens or hundreds of gratings used in alignment and/or overlay inspection). Optical system 500 may be part of a system for performing inspections (e.g., inspection apparatus 400 (FIGS. 4A and 4B)). As a non-limiting example, optical system 500 may be disposed at location 434 (FIG. 4). In such an implementation, movable reflective device 506 may direct scattered radiation from a given target to detector 428 (FIG. 4). The detector may receive the scattered radiation. The detector may generate a measurement signal based on the scattered radiation.

In some embodiments, rather than moving a single one of optical devices 502 from a first target to a second target, movable reflective device 506 may be used to select an appropriate one of optical devices 502 that is closest to the second target. In this manner, a relative movement between the targets and optical devices 502 may be significantly reduced. In a conventional inspection apparatus that relies on a single objective, the single objective may be moved from one target to another as the inspection apparatus inspects a plurality of targets (assuming a stationary reference frame of the targets—that is, moving the targets or the substrate achieves the same effect). In this inspection method, the travel time of the single objective from target to target may introduce a delay in production. Such delays may be non-negligible because of the amount of time it takes to accelerate and decelerate inertial components and precisely align the optics to the target.

In some embodiments, the aggregated delay of multiple motions may be significant. Thus, a technical significance of optical system 500 is that an amount of relative motion between targets and optical devices 502 may be reduced when inspecting multiple targets relative to an amount of motion that would be needed for a tool with a single objective. Therefore, a time duration of inspecting targets using optical system 500 may be significantly less than a time duration of inspecting targets using a single objective tool. Another technical significance of optical system 500 is that the number of radiation sources and detectors may be fewer than the number of optical devices 502 (e.g., using a single radiation source and a single detector device that is shared (or common) to two or more of the optical paths). This may reduce cost of construction and overall weight, as well as enhance scalability of optical system 500 through the use of fewer optical devices with large footprints.

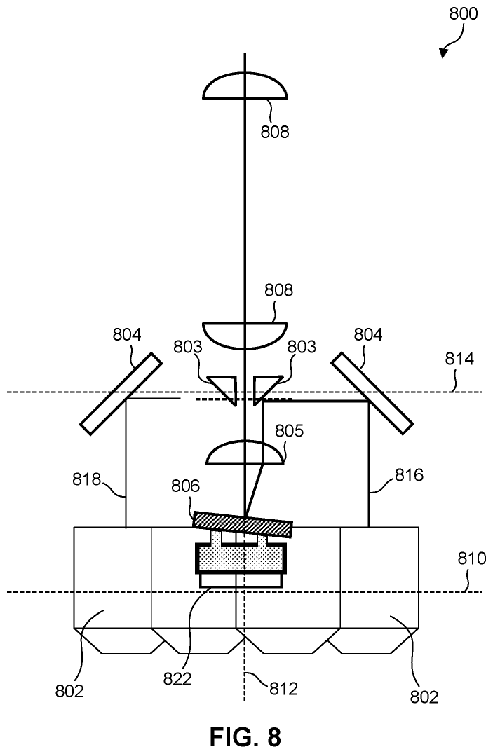

In some embodiments, each of reflective devices 504 may receive the scattered radiation from a corresponding one of optical devices 502. Movable reflective device 506 may receive the scattered radiation from each of reflective devices 504. A detector (e.g., detector 428 (FIG. 4)) may receive the scattered radiation from movable reflective device 506. The optics in optical system 500 may be arranged such that a source (or illumination) branch of the inspection system (e.g., radiation travelling toward the targets) and a detection branch of the inspection system (e.g., radiation travelling from the targets) have overlapping optical paths. For example, radiation from a source may be guided to one of targets 418 (FIG. 8) (e.g., a first target) along axis 512 and along an optical path 516 (e.g., a first optical path). After the radiation scatters from the target, the scattered radiation may be guided to detector 428 (FIG. 4) via optical path 516 and axis 512. If another target is to be inspected, movable reflective device 506 may be actuated (e.g., reoriented, redirected, or the like) so as to select a different optical path, for example, optical path 518.

In some embodiments, movable reflective device 506 may receive a beam of radiation from a source (e.g., illumination system 412 (FIG. 4)). Movable reflective device 506 may direct the beam of radiation toward targets 418 (FIG. 4) to produce the scattered radiation from the targets. Movable reflective device 506 may direct the beam of radiation using, for example, optical paths 516 or 518, based on a positional state of movable reflective device 506. Movable reflective device 506 may direct the beam of radiation, for example, via reflective devices 504 to deflect the beam of radiation toward the targets. The beam of radiation may also be transmitted through optical devices 502.

In some embodiments, a first optical path may be defined by a first one of reflective elements 504, a first one of optical devices 502, and a first one of targets 418 (FIG. 4). In a non-limiting example, the first optical path may be optical path 516 (or optical path 518)—defined by corresponding ones of an optical device, a reflective element, and a target along the optical path. A second optical path may be defined by a second one of reflective elements 504, a second one of optical devices 502, and a second one of targets 418 (FIG. 4). In a non-limiting example, the second optical path may be optical path 518 (or optical path 516)—defined by corresponding ones of an optical device, a reflective element, and a target along the optical path. Movable reflective device 506 may actuate to shift the beam of radiation between the first and second optical paths.

In some embodiments, an inspection system that implements optical system 500 may perform inspection measurements on multiple targets 418 (FIG. 4). For example, a relative movement between the targets and optical devices 502 may be generated so as to align a first one of the targets with a first one of optical devices 502. The relative movement may be achieved by moving optical devices 502 relative to the targets, moving the targets relative to optical devices 502, or both. Movable reflective device 506 may be oriented (e.g., by actuation) such that the optical path of the first one of the optical devices 502 is selected (e.g., optical path 516). A beam of radiation may be directed to the first target and the subsequent scattered radiation may be detected at detector 428 (FIG. 4), all using the first optical path. It should be appreciated that, at this point, the first one of the optical devices 502 may not be one that is most proximal to the next target to be measured (e.g., a second one of the targets). There may be another one of the optical devices 502 that is closest to the second one of the targets (e.g., a second one of the optical devices 502).

Therefore, in some embodiments, the inspection system may generate relative movement between the targets and optical devices 502 to align the second one of the targets with the second one of the optical devices 502. Movable reflective device 506 may be actuated such that the optical path of the second one of the optical devices 502 is selected (e.g., optical path 518). This shifts the beam of radiation from the first optical path to the second optical path. By using the second one of optical devices 502 to measure the second target (as opposed to using the first one of optical devices 502 to measure the second target), the relative movement between the targets and optical devices 502 may be limited so as to be less than a distance between the first and second ones of the targets. In contrast, in a scenario in which a single objective (or optical device) is moved from target to target, the distance traveled by the single objective would equal the distance between the targets. In this manner, using multiple ones of optical devices 502 may reduce distances traveled by the optical devices relative to the targets, thereby reducing the time for performing measurements on multiple targets. It should be appreciated that measurements of the first and second targets may be performed sequentially. The inspection system may complete the measurement sequence faster than an alternative measurement sequence that comprises aligning a single optical device to the first one of the targets and then to the second one of the targets.

In some embodiments, movable reflective device 506 may actuate to switch from one optical path to another at a given speed—that is, at a given rate or frequency. The frequency of the actuating of movable reflective device 506 may be based on an inverse of a time duration for performing the shifting of the beam of radiation between optical paths 516 and 518. Movable reflective device 506 may be capable of operating up to a frequency of approximately 500 Hz. The upper limit of the frequency may be greater based on the capabilities of a given actuator.

With reference to FIGS. 5A and 5B, FIG. 5B shows an arrangement of optical devices 502 at plane 510 (FIG. 5A), according to some embodiments. In some embodiments, optical devices 502 may be disposed in an array arrangement. The array arrangement may be symmetric about axis 512. An example of axial symmetry may be 12-fold symmetry (e.g., an optical device 502 may be diametrically opposite of another optical device 502). Another example of axial symmetry may be 5-fold symmetry (e.g., an optical device 502 does not have a diametrically opposite optical device). The array arrangement may be annular. For example, the array arrangement may conform to a shape of a circle or an ellipse. In some embodiments, the array arrangement may be polygonal. For example, the array arrangement may be such that optical devices 502 are disposed at vertices of a polygon shape.

In some embodiments, optical devices 502 may be disposed at equal optical distances relative to axis 512. Optical devices 502 may be disposed at equal optical distances relative to movable optical device 506. An optical magnification associated with the first one of optical devices 502 may be the same as an optical magnification associated with the second one of optical devices 502.

In some embodiments, optical devices may be arranged symmetrically and yet not limited as belonging to a particular nth-fold symmetry, as shown in FIG. 5C, for example.

With reference to FIGS. 5A and 5C, FIG. 5C shows an arrangement of optical devices 502 at plane 510 (FIG. 5A), according to some embodiments. The array arrangement may have some symmetry about axis 512 (e.g., a half portion being symmetric to another half portion). In this arrangement, optical devices 502 may be disposed at equal optical distances relative to axis 512. Optical devices 502 may be arranged such that a gap 516 is present between first and second ones of optical devices 502. Gap 520 can allow implementation of additional capabilities in an inspection system. For example, in addition to having the components for performing measurements or targets, a measurement system can comprise one or more additional sensors for other purposes.

In some embodiments, a measurement system can comprise inspection apparatus 400 (FIGS. 4A and 4B), optical system 500, as well as a second system for performing measurement(s) of the substrate and/or targets (e.g., a height or level sensor). The second system may send radiation to the substrate and/or targets via gap 520. The second system may determine a height position of a substrate (height being measured along an axis that is approximately parallel to axis 512). Gap 520 is particularly useful when optical devices 502 comprise objectives with short working distances (e.g., optical devices 502 are in focus when disposed very close to the targets). In this scenario, optical devices 502 may obstruct measurement radiation that is intended to be incident on substrate 420 (FIG. 4) at a location near axis 512. However, gap 520 can provide a line-of-sight path to areas that would normally be obstructed if optical devices 502 were to be arranged packed together without gaps. It should be appreciated that gap 520 can be incorporated in other arrangements disclosed herein.

In some embodiments, movable reflective device 506 may be used for scrambling certain properties of radiation (e.g., coherence scrambling, aberration scrambling, or the like). For example, a motion of movable reflective device 506 may be modulated and/or randomized.

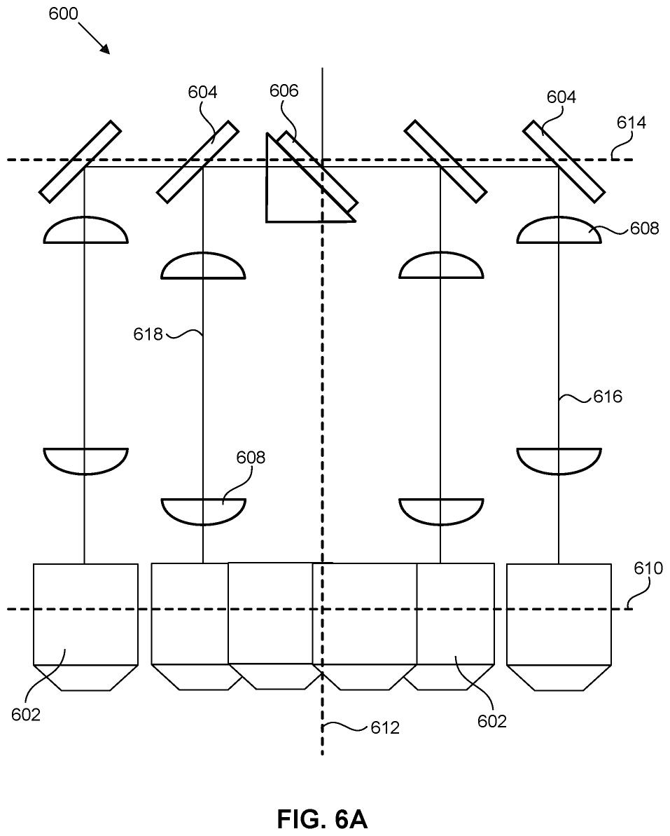

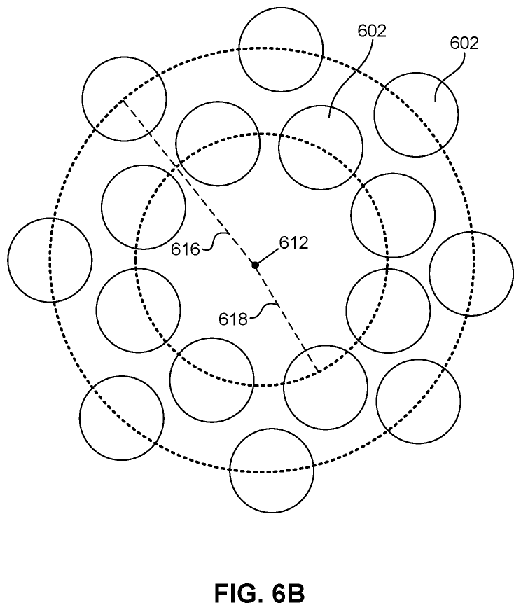

FIG. 6A shows an optical system 600, according to some embodiments. In some embodiments, optical system 600 may comprise structures and functions similar to optical system 500 that were described in reference to FIGS. 5A, 5B, and 5C. Therefore, unless otherwise noted, descriptions of elements of FIGS. 5A, 5B, and 5C may also apply to corresponding elements of FIG. 6A (e.g., reference numbers sharing the two right-most numeric digits). Furthermore, for simplicity, certain elements may not be labeled, but their structures and functions should be apparent based on similar elements that are labeled.

In some embodiments, FIG. 6A shows an example arrangement of optical components that scale the concepts described in reference to FIGS. 5A, 5B, and 5C. Optical system 600 may comprise optical devices 602, reflective devices 604, and a movable reflective device 606. Optical system 600 may also comprise a one or more lens systems 608. Planes 610 and 614, axis 612, and optical paths 616 and 618 may represent spatial relations and functions as described earlier in reference to FIG. 5A. Optical device 600 may be implemented in a system for inspecting substrates (e.g., at location 434 (FIGS. 4A and 4B)).

In some embodiments, an optical system may be scaled to the point that optical devices 602 do not fit in a single compact arrangement (e.g., do not fit in one annular arrangement). Therefore, it may be desirable to place excess optical devices 602 further away from axis 612. In some embodiments, a first arrangement may be achieved using a first portion of optical devices 602 and reflective devices 604. In FIG. 6, the inner arrangement of optical devices 602 and reflective devices 604 (ones proximal to axis 612) may be as described earlier in reference to FIGS. 5A, 5B, and 5C. A second arrangement is also envisaged, wherein a second portion of optical devices 602 and reflective devices 604 are arranged further away from axis 612. It should be appreciated that the scaling may be continued out to a third arrangement even further from axis 612, a fourth arrangement further still, and so on. And, as will be explained in reference to FIG. 6B, the arrangements can be made such that obstruction to optical paths are avoided.

In some embodiments, lens systems 608 may be disposed in a first arrangement that corresponds to the first arrangement of optical devices 602. Lens systems 608 may be disposed between planes 610 and 614. It should be appreciated that arranging additional lens systems can be extrapolated to the second, third, and/or additional arrangements. Lens systems 608 may be disposed in optical paths (e.g., optical paths 616 and/or 618). That is, lens systems 608 may be disposed such that a first optical path is defined by a first one of lens systems 608 and a second optical path is defined by a second one of lens systems, in addition to being defined by corresponding ones of optical devices 602 and reflective devices 604.

FIG. 6B shows an arrangement of optical devices 602 at plane 610 (FIG. 6A), according to some embodiments. Unless otherwise noted, descriptions of elements of FIGS. 5A, 5B, and 5C may also apply to corresponding elements of FIG. 6B (e.g., reference numbers sharing the two right-most numeric digits). Furthermore, for simplicity, certain elements may not be labeled, but their structures and functions should be apparent based on similar elements that are labeled.

In some embodiments, the inner annular arrangement of optical devices 602 (e.g., first arrangement) may be implemented such that gaps are present between optical devices 602. The gaps would also be present in corresponding arrangements of reflective devices 604 (FIG. 6A). The gaps can provide a line-of-sight path for radiation to travel unobstructed between an outer one of reflective devices 604 (FIG. 6A) (e.g., a second arrangement) and axis 612, as shown by optical path 616. Optical path 618 corresponds to a path of radiation that travels between an inner one of reflective devices 604 (FIG. 6A) and axis 612.

Briefly referring back to FIG. 6A, in some embodiments, the first and second arrangements may both be disposed at plane 614. Described differently, a plane of the first arrangement (e.g., a second plane) may coincide with a plane of the second arrangement (e.g., a third plane coinciding with the second plane).

Explained differently, in some embodiments, two or more of optical devices 602 may be disposed in a first arrangement about axis 612. Another two or more of optical devices 602 may be disposed at plane 610 (e.g., a first plane) and in a second arrangement. The second arrangement may be similar in geometry to the first arrangement, but larger and surrounding the first arrangement. That is, a perimeter of the second arrangement of optical devices 602 may be larger than a perimeter of the first arrangement of optical devices 602. The first arrangement of optical devices 602 may be disposed interior to the second arrangement of optical devices 602. Two or more of reflective devices 604 may be disposed in a first arrangement corresponding to the first arrangement of optical devices 602. Another two or more of reflective devices 604 may be disposed in a second arrangement corresponding to the second arrangement of optical devices 602.

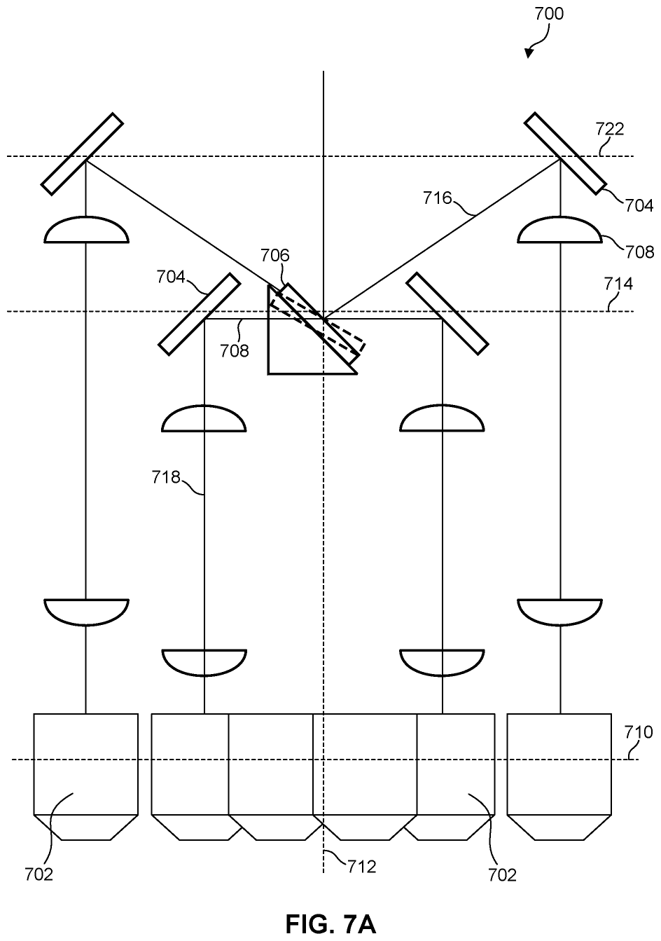

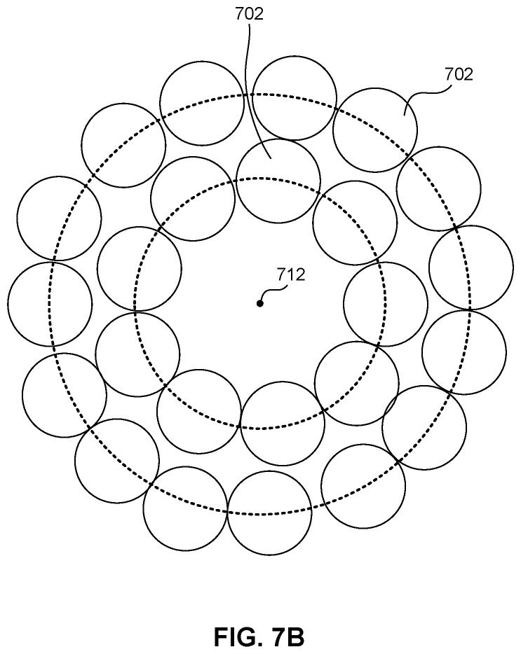

In some embodiments, the second arrangement of reflective devices 604 may be disposed at plane 614 (e.g., a second plane). However, other planes may be used, as will be discussed in reference to FIGS. 7A and 7B.

It should be appreciated, that in some embodiments, optical paths in the first arrangement may have same optical distances. Similarly, optical paths in the second arrangement may have same optical distances. However, due to the second arrangement being positioned further from axis 612, an optical distance of a path in the first arrangement may be different from an optical distance of a path in the second arrangement. In some embodiments, it is to be appreciated that additional optical components may be implemented so as to lengthen certain optical paths so that all optical paths have same optical distances (e.g., introducing a beam-delaying material or deflecting a path using reflectors for sending radiation through a longer path).

In some embodiments, the concept of gap 520 (FIG. 5C) can be worked into the first, second, and/or further arrangements so as to allow a second inspection system to send radiation to a substrate via gap 520 (FIG. 5C).

FIG. 7A shows an optical system 700, according to some embodiments. In some embodiments, optical system 700 may comprise structures and functions similar to optical system 500 and/or 600 that were described in reference to FIGS. 5A, 5B, 5C. 6A, and/or 6B. Therefore, unless otherwise noted, descriptions of elements of FIGS. 5A, 5B, 5C, 6A, and 6B may also apply to corresponding elements of FIG. 7A (e.g., reference numbers sharing the two right-most numeric digits). Furthermore, for simplicity, certain elements may not be labeled, but their structures and functions should be apparent based on similar elements that are labeled.

In some embodiments, FIG. 7A shows an example arrangement of optical components that scale the concepts described in reference to FIGS. 5A, 5B, 5C, 6A, and/or 6B. Optical system 700 may comprise optical devices 702, reflective devices 704, and a movable reflective device 706. Optical system 700 may also comprise a one or more lens systems 708. Planes 710 and 714, axis 712, and optical paths 716 and 718 may represent spatial relations and functions as described earlier in reference to FIG. 5A. Optical device 700 may be implemented in a system for inspecting substrates (e.g., at location 434 (FIGS. 4A and 4B)).

A difference between FIGS. 6A and 7A is that, in some embodiments, the second arrangement of reflective devices 704 may be disposed at plane 722 (e.g., a third plane). This may be particularly useful for increasing the packing density of optical objectives 702, as shown in FIG. 7B. The gaps that were present in FIG. 6B are not present in the arrangement shown in FIG. 7B. That is, optical devices 702 in the interior arrangement (e.g., first arrangement) may be disposed so close together such that a line-of-sight obstruction is present between axis 712 and at least one of optical devices 702 in the outer arrangement (e.g., second arrangement). Correspondingly, reflective devices 704 in such an arrangement would present a line-of-sight obstruction between movable reflective device 706 and one of the reflective devices in the second arrangement, if planes 714 and 722 were coincident. Therefore, plane 722 may be offset from plane 714 such that line-of-sight may be established between movable reflective device 706 and reflective devices 704 in the second arrangement.

Before describing movements of movable reflective device 706, it may be instructive to first define a reference frame. Planes 710, 714, and/or 722 may define a horizontal direction and axis 712 may define a zenith direction. An azimuthal direction or rotation may be defined about axis 712. While an inclination angle may be defined as starting at zero at the zenith direction, it should be appreciated that an elevation angle may be the complement of the inclination angle (i.e., a line-of-sight may have an elevation angle of zero when pointed horizontally and the elevation angle may increase as the line-of-sight is made to point more vertically). An origin of the reference frame may be defined at an intersection of axis 712 to a surface of movable reflective device 706.

In some embodiments, an optical path may have a portion of its path set approximately parallel to a plane of an arrangement of optical devices 702. Shown in FIG. 7A as a non-limiting example, the horizontal portion of optical path 718 is approximately parallel to plane 714. Furthermore, another optical path may have a portion of its path set at a non-zero elevation angle with respect to a plane of an arrangement of optical devices 702. Shown in FIG. 7A as a non-limiting example, there is a portion of optical path 716 that is tilted at a non-zero angle with respect to plane 714. The drawings illustrate non-limiting examples and it should be appreciated that other arrangements may be envisaged. For example, arrangements of reflective devices 704 may be flipped such that reflective devices 704 at plane 714 are instead disposed at plane 722 while reflective devices 704 at plane 722 are instead disposed at plane 714. Corresponding adjustments of other optics (e.g., lens systems 708) are also envisaged.

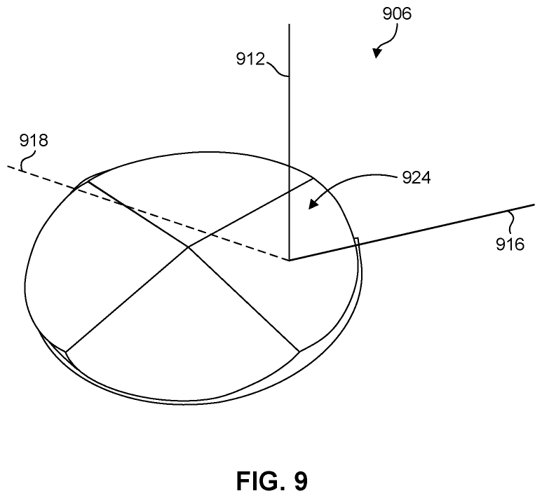

In some embodiments, movable reflective device 706 may be disposed at plane 714 (e.g., a second plane). Movable reflective device 706 may be adjusted so as to rotate its optical direction about axis 712 (e.g., to achieve azimuthal adjustment). Rotation is not the only manner of achieving azimuthal adjustment, as will be described later in reference to FIG. 9. Movable reflective device 706 may also be adjusted so as to adjust an elevation orientation of a surface of movable reflective device 706—that is, adjust in a direction that is parallel to axis 712. The adjustment in elevation allows for gaining line-of-sight access to reflective devices 704 that are disposed at plane 722 (e.g., reflective devices in the second arrangement). In this manner, it is possible to overcome line-of-sight issues that result from a tight packing of the optical objectives 702, and corresponding reflective devices 704, as shown in FIG. 7B.

In some embodiments, optical path lengths, lens system dispositions, and use of gap 520 (FIG. 5) may be also be implemented as described in reference to other figures.

FIG. 8 shows an optical system 800, according to some embodiments. In some embodiments, optical system 800 may comprise structures and functions similar to optical system 500, 600, and/or 700 that were described in reference to FIGS. 5A, 5B, 5C. 6A, 6B, 7A and/or 7B. Therefore, unless otherwise noted, descriptions of elements of FIGS. 5A, 5B, 5C, 6A, 6B, 7A, and 7B may also apply to corresponding elements of FIG. 8 (e.g., reference numbers sharing the two right-most numeric digits). Furthermore, for simplicity, certain elements may not be labeled, but their structures and functions should be apparent based on similar elements that are labeled.

In some embodiments, optical system 800 may comprise optical devices 802, reflective devices 804, a movable reflective device 806, additional reflective devices 803 and a refractive device 805 (e.g., a lens). Optical system 800 may also comprise a one or more lens systems 808. Planes 810 and 814, axis 812, and optical paths 816 and 818 may represent spatial relations and functions as described earlier in reference to corresponding elements in FIG. 5A. Optical system 800 may be implemented in a system for inspecting substrates (e.g., at location 434 (FIGS. 4A and 4B)).

In some embodiments, reflective devices 804 and additional reflective devices 803 may be disposed at plane 814 (e.g., a second plane). Additional reflective devices 803 may be disposed in an arrangement that corresponds to the arrangement of reflective devices 804 (e.g., one-to-one correspondence). Additional reflective devices 803 may be disposed closer to axis 812 than optical devices 804. In contrast with some of the previous figures, movable reflective device 806 may be disposed at or near plane 810 (e.g., a first plane), as opposed to near plane 814. Refractive device 805 may be disposed between plane 814 and movable reflective device 806. And while movable reflective device 806 may be illustrated as being in the forefront of FIG. 8, this done for clarity and it should be appreciated that movable reflective device 806 may be disposed inside of an arrangement of optical devices 802 (e.g., disposed at axis 802).

In some embodiments, an optical path 816 may be defined by one of optical devices 802, one of reflective devices 804, and one of additional reflective devices 803 (e.g., a first optical path defined by first ones of the previously named optical elements). A similar relationship can be defined for optical path 818 and corresponding optical elements.

In some embodiments, movable reflective device 806 may actuate to switch from one optical path to another. Movable reflective device 806 may receive a beam of radiation from a radiation source via axis 812. Movable reflective device 806 may direct the beam toward one of additional reflective devices 803 that corresponds with an optical path as set by movable reflective device 806. Movable reflective device 806 may receive scattered radiation from a target via an optical path as set by movable reflective device 806. Each of additional reflective devices 803 may receive the scattered radiation from a corresponding one of reflective devices 804. Refractive device 805 serves to deflect a path of radiation to connect the optical paths to axis 812.

In some embodiments, for example those related to FIG. 6A, radiation relayed between movable reflective device 606 and reflective devices 604 was oriented parallel to plane 614 without any component traveling parallel to axis 612. However, in embodiments related to FIG. 8, the positioning of movable reflective device 804, the radiation relayed between movable reflective device 806 and reflective devices 804 has a portion of the path oriented parallel to axis 812, which is achieved using additional reflective devices 803 and refractive device 805. The configurability of optical components is a desirable feature for implementation of optical systems. The differences from figure to figure are more than just mere rearrangement of optical paths. As an example, the configuration in FIG. 8 may be more optimal to implement given depending on volume constraints imposed by a particular inspection tool or application.

In some embodiments, movable device 806 may be subject to undue heating due to, for example, actuation and being a common point for all radiation paths. Therefore, movable reflective device 806 may be coupled to a heat-exchange device 822 (e.g., a cooling plate). Heat-exchange device 822 may be in thermal communication with a cooling system to regulate, maintain, or otherwise adjust a temperature of movable reflective device 806. The use of heat-exchange device 822 may also be implemented in embodiments related to other figures.

In some embodiments, movable reflective device 806 may comprise a galvanometer (or galvo), a beam-steering mirror, a mirror on a rotating/translating actuator (e.g., mirror on a hexapod stage), a digital micromirror device (DMD), spatial light modulators, single or multiple mirrors, single or multiple prisms, a combination of one or more mirrors and one or more prisms-non-limiting examples. Movable reflective device 806 may have multiple reflective surfaces (e.g., facets). Furthermore, movable reflective device 806 may comprise a surface having a curvature to focus/defocus a beam of radiation, a surface with a given texture and/or coating to control properties of radiation (e.g., polarization), or the like. If surfaces affect a property of radiation in an undesirable manner, then additional optics may be implemented at some point in the path of radiation to provide correction (e.g., a waveplate at the detector).

FIG. 9 shows a movable reflective device 906, according to some embodiments. In some embodiments, features illustrated in FIG. 9 may be similar to features described in reference to FIGS. 5A, 5B, 5C, 6A, 6B, 7A, 7B and/or 8. Therefore, unless otherwise noted, descriptions of elements of FIGS. 5A, 5B, 5C, 6A, 6B, 7A, 7B, and 8 may also apply to corresponding elements of FIG. 9 (e.g., reference numbers sharing the two right-most numeric digits). Furthermore, it should be appreciated that movable reflective device 906 may be used in place of movable reflective devices 506 (FIG. 5A), 606 (FIG. 6A), 706 (FIG. 7A), or 806 (FIG. 8).

In some embodiments, movable reflective device 906 may comprise facets 924. Movable reflective device 906 may be disposed in the path of a axis 912. The particular one of facets 924 may cause optical 916 to be selected. In some embodiments, movable reflective device 906 may be actuated (e.g., translated) such that a different one of facets 924 be disposed in the path of axis 912. The different one of facets 924 may cause optical path 918 to be selected. Movable reflective device 906 may also be tilted and/or rotated to shift a path of radiation between different optical paths.

In some embodiments, a reflective device may be more generally referred to as an “optical sub-system.” A movable reflective device may be more generally referred to as a “central beam steering element.” The term “optical sub-elements” (and qualifiers, such as reflective or transmissive) may be used herein to refer to sub-elements of a central beam steering element.

In some embodiments, a measurement system (e.g., inspection apparatus 400 (FIGS. 4A and 4B) that uses optical systems described herein (e.g., optical system 900 (FIG. 9)) may perform a measurement when a movement of a movable device is in a stable phase of its motion (e.g., minimal acceleration and/or jitter). It is to be appreciated that a movable device that begins at rest and ends at rest may have at least two phases of motion, for example, an acceleration phase and a deceleration phase. There may also be phases of constant speed and combinations of phases. It should be appreciated that instabilities, such as jitter and vibration, can also be present during motion. For example, as a moving object approaches a setpoint velocity there, there may be some final jitter due to a transient from full speed to stop. To address this problem, the measurement system may perform a measurement during a settling period of a motion of the central beam steering device. Furthermore, a predictable or measureable jitter can be applied as a correction to the measurement using, for example, a transfer function. In this manner, a speed of measurements may be increased, further enhancing throughput.

In some embodiments, an optical system (e.g., optical system 900 (FIG. 9)) may also comprise an actuation system. The actuation system can actuate the central beam steering system using a counter rotating balance mass. The actuation system may react against a counter rotating balance mass.

In some embodiments, an optical system (e.g., optical system 900 (FIG. 9)) may also comprise a support structure that minimize a transfer of kinetic energy from a moving component (e.g., central beam steering element) to other sensitive optical devices, such as objectives and reflectors. The support structure may shunt acceleration reactions to a more massive frame (e.g., a frame of a measurement system) that is different from the frame on which the optics of the optical system are mounted. In this manner, kinetic excitation of the optics of the optical system may be minimized.

The embodiments may further be described using the following clauses:
1. A system comprising:
   optical devices disposed at a first plane and around an axis of the system and configured to receive scattered radiation from targets;
   reflective devices disposed at at least a second plane and around the axis, each of the reflective devices is configured to receive the scattered radiation from a corresponding one of the optical devices;
   a movable reflective device disposed along the axis and configured to receive the scattered radiation from each of the reflective devices; and
   a detector configured to receive the scattered radiation from the movable reflective device.
2. The system of clause 1, wherein the optical devices are disposed in an array arrangement that is symmetric about the axis.
3. The system of clause 2, wherein the array arrangement is annular or polygonal.
4. The system of clause 1, wherein first and second ones of the optical devices are disposed at equal optical distances relative to the movable reflective device.
5. The system of clause 1, wherein the movable reflective device is further configured to direct a beam of radiation toward the targets to produce the scattered radiation from the targets.
6. The system of clause 1, wherein the optical devices are objectives configured to collect the scattered radiation for detection.
7. The system of clause 1, wherein:
   a first optical path is defined by first ones of the targets, optical devices, and reflective devices;
   a second optical path is defined by second ones of the targets, optical devices, and reflective devices; and
   the movable reflective device is further configured to:
      direct a beam toward the targets via the reflective devices; and
      actuate to shift the beam between the first and second optical paths.
8. The system of clause 7, wherein the system is configured to:
   align the first ones of the targets and optical devices;
   then generate a relative movement between the targets and optical devices to align the second ones of the targets and optical devices; and
   perform measurements of the targets based on the movable reflective device performing the shifting of the beam between the first and second paths so as to limit the relative movement to be less than a distance between the first and second ones of the targets.
9. The system of clause 8, wherein the system is further configured to perform the measurements of the targets in sequence based on the actuating of the movable reflective device.
10. The system of clause 7, wherein:
   a measurement sequence comprises performing the aligning of the second ones of the targets and optical devices being after the aligning of the first ones of the targets and optical devices;
   the system is further configured to complete the measurement sequence faster than an alternative measurement sequence that comprises aligning a single optical device to the first one of the targets and then to the second one of the targets.
11. The system of clause 7, wherein the movable reflective device comprises a rotatable reflector configured to rotate to engage the first or second optical paths.
12. The system of clause 7, wherein the movable reflective device comprises a multi-faceted reflector configured to translate and/or rotate to engage the first or second optical paths.
13. The system of clause 7, wherein the movable reflective device comprises a galvo configured to rotate to engage the first or second optical paths.
14. The system of clause 7, wherein:
   a frequency of the actuating of the movable reflective device is based on an inverse of a time duration for performing the shifting of the beam; and
   the movable reflective device is further configured to operate at the frequency, wherein the frequency is approximately 500 Hz or greater.
15. The system of clause 7, wherein, based on a state of the movable reflective device, the system is further configured to propagate the scattered radiation along the first optical or the second optical path.
16. The system of clause 7, wherein lengths of the first and second optical paths are approximately same.
17. The system of clause 16, wherein an optical magnification associated with the first one of the optical devices is same as an optical magnification associated with the second one of the optical devices.
18. The system of clause 7, further comprising a radiation source configured to generate the beam to direct toward the movable reflective device along the axis, wherein the movable reflective device is further configured to direct the beam from the axis to the first optical path or from the axis to the second optical path.
19. The system of clause 1, wherein the movable reflective device is further configured to direct the scattered radiation toward the detector using the first optical path or using the second optical path.
20. The system of clause 7, further comprising lens systems.
21. The system of clause 20, wherein the lens systems comprise 4f lens systems.
22. The system of clause 20, wherein the lens systems are disposed such that:
   the first optical path is further defined by a first one of the lens systems; and
   the second optical path is further defined by a second one of the lens systems.
23. The system of clause 1, wherein an arrangement of the optical devices comprises a gap between first and second ones of the optical devices.
24. The system of clause 23, further comprising another system configured to perform a measurement of the substrate and/or targets by sending radiation via the gap.
25. The system of clause 24, wherein:
   the another system comprises a level sensor configured to determine a height position of the substrate; and
   an axis of the height position is approximately parallel to the axis of the system.
26. The system of clause 1, wherein:
   two or more of the optical devices are disposed in a first arrangement about the axis; and
   two or more of the reflective devices are disposed in a first arrangement corresponding to the first arrangement of the optical devices.
27. The system of clause 26, further comprising lens systems disposed between the first and second planes and in a first arrangement corresponding to the first arrangement of the optical devices.
28. The system of clause 26, wherein:
   another two or more of the optical devices are disposed at the first plane and in a second arrangement; and
   another two or more of the reflective devices are disposed in a second arrangement corresponding to the second arrangement of the optical devices.
29. The system of clause 28, wherein:
   a perimeter of the second arrangement of the optical devices is larger than a perimeter of the first arrangement of the optical devices; and
   the first arrangement is disposed interior to the second arrangement.
30. The system of clause 28, wherein the second arrangement of the reflective devices is disposed at the second plane.
31. The system of clause 30, wherein:
   the two or more reflective devices in the first arrangement are disposed such that at least one gap is present between the two or more of the reflective devices; and
   the movable reflective device is further configured to direct a beam of radiation to the second arrangement through the gap.
32. The system of clause 31, wherein the second arrangement of the reflective devices is disposed at a third plane different from the second plane.
33. The system of clause 32, wherein the movable reflective device is disposed at the second plane and is configured to actuate such that a surface of movable reflective device is oriented to optically interact with one of the reflective devices at the second plane or one of the reflective devices at the third plane.
34. The system of clause 26, further comprising additional reflective devices disposed at least at the second plane, around the axis, and closer to the axis than the reflective devices, wherein:
   each of the additional reflective devices are configured to receive the scattered radiation from a corresponding one of the reflective devices; and
   the movable reflective device is disposed at the first plane and is configured to actuate such that a surface of movable reflective device is oriented to optically interact with one of the additionally reflective devices at the second plane.
35. The system of clause 34, wherein:
   a first optical path is defined by first ones of the targets, optical devices, reflective devices, and additional reflective devices;
   a second optical path is defined by second ones of the targets, optical devices, reflective devices, and additional reflective devices; and
   the movable reflective device is further configured to:
      direct a beam toward the targets via the additional reflective devices; and
      actuate to shift the beam between the first and second optical paths.
36. The system of clause 35, wherein, between the first one of the additional reflective elements and the movable reflective device, the first optical path comprises a portion oriented parallel to the axis.
37. The system of clause 1, wherein the movable reflective device comprises a galvanometer, a beam-steering mirror, a faceted surface, and/or a digital micromirror device.
38. The system of clause 1, further comprising a heat-exchange device thermally coupled to the movable reflective device and configured to maintain regulate a temperature of the movable reflective device.
39. The system of clause 1, wherein the axis of the system is a central axis of the system.
40. An optical system comprising:
   optical devices disposed at a first plane and around a axis of the system and configured to receive scattered radiation from targets;
   reflective devices disposed at at least a second plane and around the axis, each of the reflective devices are configured to receive the scattered radiation from a corresponding one of the optical devices; and
   a movable reflective device positioned disposed along the axis and configured to receive the scattered radiation from each of the reflective devices.
41. A system comprising:
   optical devices disposed at a first plane and around an axis of the system and configured to illuminate and/or receive scattered radiation from objects;
   optical sub-systems disposed at at least a second plane and around the axis, wherein each of the optical sub-systems is configured to illuminate and/or receive the scattered radiation from a corresponding one of the objects; and
   a central beam steering element configured to route radiation between the first plane the optical sub-systems to illuminate and/or receive the scattered radiation from the objects.
42. The system of clause 41, further comprising a detector configured to receive the scattered radiation from the central beam steering element.
43. The system of clause 42, wherein the detector is disposed at the first plane.
44. The system of clause 42, wherein the detector is disposed at a third plane that is different from the first plane.
45. The system of clause 41, wherein the central beam steering element comprises one or more reflective and/or transmissive optical sub-elements.
46. The system of clause 45, wherein:
   the central beam steering element is configured to translate and/or rotate to control a propagation direction of radiation;
   the one or more reflective optical sub-elements are configured to translate and/or rotate to control a propagation direction of radiation; and/or
   the one or more transmissive optical sub-elements are configured to translate and/or rotate to control a propagation direction of radiation.
47. The system of clause 41, wherein the central beam steering element further comprises: optical acoustic wafers to control a propagation direction of radiation; and/or electro optically induced wafers to control a propagation direction of radiation.
48. The system of clause 41, wherein the system is configured to perform a measurement of the objects during a settling period of a motion of the central beam steering element.
49. The system of clause 41, further comprising an actuation system configured to actuate the central beam steering element using a counter rotating balance mass.
50. The system of clause 41, further comprising a support structure configured to support the central beam steering element and to shunt acceleration reactions to a frame that is different from a frame of the optical devices and optical sub-systems.
51. The system of clause 41, wherein:
   the central beam steering element comprises an actuation system comprising first and second actuators;
   the first actuator is configured to allow bulk adjust a motion of the central beam steering element; and
   the second actuator is configured to fine adjust the motion of the central beam steering element.
52. The system of clause 51, wherein the actuation system is configured to move the central beam steering element to correct a propagation direction of radiation according to a given alignment.
53. The system of clause 41, wherein the central beam steering element comprises an optical surface configured to interact with a beam of radiation.
54. The system of clause 41, wherein the optical surface is configured to focus and/or defocus a beam of radiation incident on the optical surface.
55. The system of clause 54, wherein the optical surface is configured to adjust a property of the beam of radiation.
56. The system of clause 41, wherein the central beam steering element is further configured to move according to a modulation and/or randomization process.
57. The system of clause 56, wherein the central beam steering element is further configured to scramble a property of a beam of radiation based on the modulation and/or randomization process.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation.” “beam of radiation” or the like as used herein can encompass all types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light.” “illumination,” or the like can refer to non-matter radiation (e.g., photons, UV. X-ray, or the like). Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A system comprising:
optical devices disposed at a first plane and around an axis of the system and configured to receive scattered radiation from targets;
reflective devices disposed at at least a second plane and around the axis, each of the reflective devices is configured to receive the scattered radiation from a corresponding one of the optical devices;
a movable reflective device disposed along the axis and configured to receive the scattered radiation from each of the reflective devices; and
a detector configured to receive the scattered radiation from the movable reflective device.

2. The system of claim 1, wherein the optical devices are disposed in an array arrangement that is symmetric about the axis.

3. The system of claim 2, wherein the array arrangement is annular or polygonal.

4. The system of claim 1, wherein first and second ones of the optical devices are disposed at equal optical distances relative to the movable reflective device.

5. The system of claim 1, wherein the movable reflective device is further configured to direct a beam of radiation toward the targets to produce the scattered radiation from the targets.

6. The system of claim 1, wherein the optical devices are objectives configured to collect the scattered radiation for detection.

7. The system of claim 1, wherein:
a first optical path is defined by first ones of the targets, optical devices, and reflective devices;
a second optical path is defined by second ones of the targets, optical devices, and reflective devices; and
the movable reflective device is further configured to:
direct a beam toward the targets via the reflective devices; and
actuate to shift the beam between the first and second optical paths.

8. The system of claim 7, wherein the system is configured to:
align the first ones of the targets and optical devices;
then generate a relative movement between the targets and optical devices to align the second ones of the targets and optical devices; and
perform measurements of the targets based on the movable reflective device performing the shifting of the beam between the first and second paths so as to limit the relative movement to be less than a distance between the first and second ones of the targets.

9. The system of claim 8, wherein the system is further configured to perform the measurements of the targets in sequence based on the actuating of the movable reflective device.

10. The system of claim 7, wherein:
a measurement sequence comprises performing the aligning of the second ones of the targets and optical devices being after the aligning of the first ones of the targets and optical devices;
the system is further configured to complete the measurement sequence faster than an alternative measurement sequence that comprises aligning a single optical device to the first one of the targets and then to the second one of the targets.

11. The system of claim 7, wherein the movable reflective device comprises a rotatable reflector configured to rotate to engage the first or second optical paths.

12. The system of claim 7, wherein the movable reflective device comprises a multi-faceted reflector configured to translate and/or rotate to engage the first or second optical paths.

13. The system of claim 7, wherein the movable reflective device comprises a galvo configured to rotate to engage the first or second optical paths.

14. The system of claim 7, wherein:
a frequency of the actuating of the movable reflective device is based on an inverse of a time duration for performing the shifting of the beam; and
the movable reflective device is further configured to operate at the frequency, wherein the frequency is approximately 500 Hz or greater.

15. The system of claim 7, wherein, based on a state of the movable reflective device, the system is further configured to propagate the scattered radiation along the first optical or the second optical path.

16. The system of claim 7, wherein lengths of the first and second optical paths are approximately same.

17. The system of claim 16, wherein an optical magnification associated with the first one of the optical devices is same as an optical magnification associated with the second one of the optical devices.

18. The system of claim 7, further comprising a radiation source configured to generate the beam to direct toward the movable reflective device along the axis, wherein the movable reflective device is further configured to direct the beam from the axis to the first optical path or from the axis to the second optical path.

19. The system of claim 1, wherein the movable reflective device is further configured to direct the scattered radiation toward the detector using the first optical path or using the second optical path.

20. The system of claim 1, wherein an arrangement of the optical devices comprises a gap between first and second ones of the optical devices.
